(19) United States
(12) Patent Application Publication
(10) Pub. No.: US 2026/0251751 A1
(43) Pub. Date: Aug. 27, 2026

(54) COMPENSATING CIRCUIT AND COMPENSATING METHOD

(71) Applicant: Realtek Semiconductor Corp., Hsinchu (TW)

(72) Inventors: Wen-Yung Lee, Hsinchu (TW); YING YANG, Suzhou City (CN)

(73) Assignee: Realtek Semiconductor Corp., Hsinchu (TW)

(21) Appl. No.: 19/533,277

(22) Filed: Feb. 8, 2026

(30) Foreign Application Priority Data
Feb. 24, 2025 (CN) 202510205642.3

(51) Int. Cl. G01S 7/288; G01S 13/00; G01S 13/58

(52) U.S. Cl. CPC G01S 7/2883; G01S 7/2886; G01S 13/006; G01S 13/581

(57) ABSTRACT

A compensating circuit includes a matching circuit, for matching an initial signal and a transformed signal to generate a matched signal; a calculating circuit, coupled to the matching circuit, for calculating a function of the matched signal; a phase-rotating circuit, coupled to the calculating circuit, for rotating a phase of the function according to a determined phase to generate a phase-rotated function; a determining circuit, coupled to the phase-rotating circuit, for determining a parameter according to the phase-rotated function; and a mixing circuit, coupled to the determining circuit, for mixing the parameter and the transformed signal to generate a compensated signal.

### BACKGROUND OF THE INVENTION

### 1. Field of the Invention

The present invention relates to a circuit and a method used in a wireless communication system, and more particularly, to a compensating circuit and a compensating method for improving sensing accuracy.

### 2. Description of the Prior Art

A sensing device is an electronic device that senses a presence, a velocity and/or a distance of a target object. The sensing device comprises an In-phase Quadrature (IQ) modulator and an IQ demodulator. The IQ modulator and the IQ demodulator use a doubled oscillation frequency, and then a frequency division is performed to reduce an impact of the oscillation path. However, there will be a subsequent IQ phase difference due to different time instants for capturing the doubled oscillation frequency during the frequency division process. This IQ phase difference reduces a sensing accuracy of the sensing device. Thus, how to compensate the IQ phase difference to improve the sensing accuracy is an important problem to be solved.

### SUMMARY OF THE INVENTION

The present invention provides a compensating circuit and a compensating method to solve the abovementioned problem.

A compensating circuit comprises: a matching circuit, for matching an initial signal and a transformed signal to generate a matched signal; a calculating circuit, coupled to the matching circuit, for calculating a function of the matched signal; a phase-rotating circuit, coupled to the calculating circuit, for rotating a phase of the function according to a determined phase to generate a phase-rotated function; a determining circuit, coupled to the phase-rotating circuit, for determining a parameter according to the phase-rotated function; and a mixing circuit, coupled to the determining circuit, for mixing the parameter and the transformed signal to generate a compensated signal.

A compensating method comprises: matching an initial signal and a transformed signal to generate a matched signal; calculating a function of the matched signal; rotating a phase of the function according to a determined phase to generate a phase-rotated function; determining a parameter according to the phase-rotated function; and mixing the parameter and the transformed signal to generate a compensated signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a sensing device according to an example of the present invention.

FIG. 2 is a schematic diagram of an IQ modulator according to an example of the present invention.

FIG. 3 is a schematic diagram of an IQ demodulator according to an example of the present invention.

FIG. 4 is a schematic diagram of a frequency division result of an IQ demodulator according to an example of the present invention.

FIG. 5 is a schematic diagram of a compensating circuit according to an example of the present invention.

FIG. 6 is a flowchart of a process according to an example of the present invention.

FIG. 7 is a flowchart of a process according to an example of the present invention.

### DETAILED DESCRIPTION

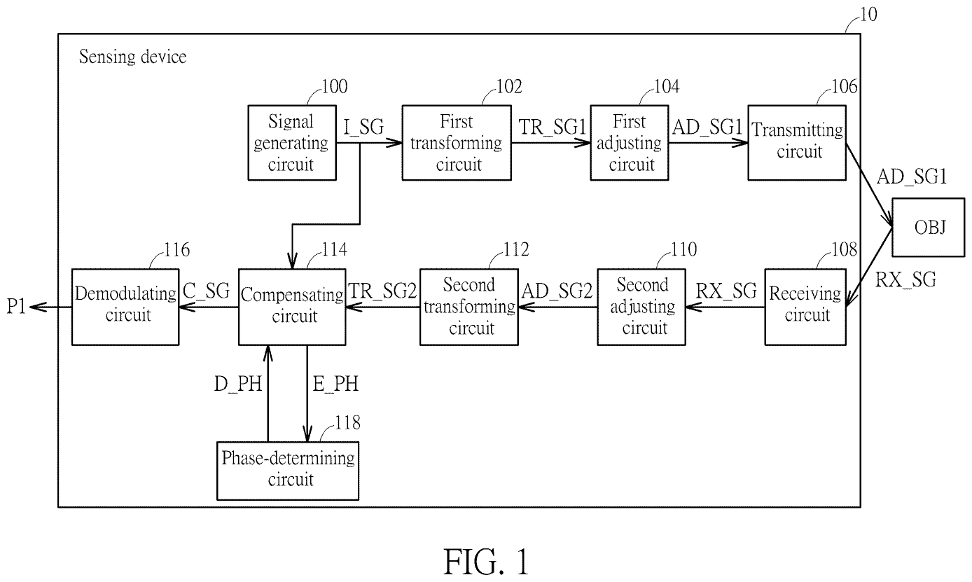

FIG. 1 is a schematic diagram of a sensing device 10 according to an example of the present invention. The sensing device 10 may be applied in a wireless communication system such as a wireless local area network (WLAN) (e.g. WiFi), a Long Term Evolution (LTE) system, a 5th generation (5G) system, etc. The sensing device 10 may support an Institute of Electrical and Electronics Engineers (IEEE) standard (e.g., 802.11ax, 802.11be or a subsequent version). The IEEE 802.11 standard may support an Orthogonal Frequency Division Multiple Access (OFDMA) and/or a Multi-User Multiple-Input Multiple-Output (MU-MIMO). In one example, the sensing device 10 may be a Frequency Modulated Continuous Wave (FMCW) device. The sensing device 10 senses a presence, a velocity and/or a distance of a target object by transmitting a FMCW signal and receiving its reflected signal.

In FIG. 1, the sensing device 10 comprises a signal generating circuit 100, a first transforming circuit 102, a first adjusting circuit 104, a transmitting circuit 106, a receiving circuit 108, a second adjusting circuit 110, a second transforming circuit 112, a compensating circuit 114, a demodulating circuit 116 and a phase-determining circuit 118. The signal generating circuit 100, the first transforming circuit 102, the first adjusting circuit 104 and the transmitting circuit 106 can be seen as a transmitter. The receiving circuit 108, the second adjusting circuit 110, the second transforming circuit 112, the compensating circuit 114, the demodulating circuit 116 and the phase-determining circuit 118 can be seen as a receiver.

In the transmitter, the signal generating circuit 100 is configured to generate an initial signal I_SG. The initial signal I_SG comprises a chirp signal. The first transforming circuit 102 is coupled to the signal generating circuit 100, and is configured to transform the initial signal I_SG to a first transformed signal TR_SG1. The first adjusting circuit 104 is coupled to the first transforming circuit 102, and configured to adjust the first transformed signal TR_SG1 to generate a first adjusted signal AD_SG1. The transmitting circuit 106 is coupled to the first adjusting circuit 104, and is configured to transmit the first adjusted signal AD_SG1.

In the receiver, the receiving circuit 108 is configured to receive a received signal RX_SG corresponding to the first adjusted signal AD_SG1. In one example, the received signal RX_SG is a signal received by the receiving circuit 108 after the transmitted first adjustment signal AD_SG1 is reflected by a sensing object OBJ. The second adjusting circuit 110 is coupled to the receiving circuit 108, and is configured to adjust the received signal RX_SG to generate a second adjusted signal AD_SG2. The second transforming circuit 112 is coupled to the second adjusting circuit 110, and is configured to transform the second adjusted signal AD_SG2 to a second transformed signal TR_SG2. The compensating circuit 114 is coupled to the signal generating circuit 100 and the second transforming circuit 112, and is configured to determine an estimated phase E_PH and compensate a phase of the second transformed signal TR_SG2 according to the initial signal I_SG and a determined phase D_PH to generate a compensated signal C_SG. The demodulating circuit 116 is coupled to the compensating circuit 114, and is configured to demodulate the compensated signal C_SG to generate at least one parameter P1. The phase-determining circuit 118 is coupled to the compensating circuit 114, and is configured to determine the determined phase D_PH according to the estimated phase E_PH.

In one example, the first transforming circuit 102 comprises a digital-to-analog converter (DAC). In one example, the first adjusting circuit 104 comprises a first analog front end (AFE). The first AFE comprises at least one of a filter, an amplifier, a mixer, an oscillator, an IQ modulator and an integrated circuit, but is not limited herein. In one example, the second adjusting circuit 112 comprises a second AFE. The second AFE comprises at least one of a filter, an amplifier, a mixer, an oscillator, an IQ demodulator and an integrated circuit, but is not limited herein. It should be noted that the amplifier in the first AFE and the amplifier in the second AFE may be the same or different types of amplifiers. For example, the amplifier in the first AFE is a power amplifier (PA) and the amplifier in the second AFE is a low-noise amplifier (LNA), but not limited therein. Similarly, the types of the filters, the mixers, the oscillators or the integrated circuits in the first AFE and the second AFE may be the same or different. In one example, the second adjusting circuit 112 comprises an analog-to-digital converter (ADC). In one example, the demodulating circuit 116 comprises a Fast Fourier Transform (FFT) circuit. The FFT circuit performs at least one of a Range-FFT, a Doppler-FFT and an Angle-FFT for the compensated signal C_SG.

In one example, the initial signal I_SG, the second transformed signal TR_SG2 and the compensated signal C_SG are digital signals. In one example, the first transformed signal TR_SG1, the first adjusted signal AD_SG1, the received signal RX_SG and the second adjusted signal AD_SG2 are analog signals. In one example, the at least one parameter P1 comprises at least one of a range, a velocity and an angle of arrival (AoA). The range is a range (or distance) between the sensing device 10 and the sensing object OBJ. The velocity is a velocity (or speed) of the sensing object OBJ. The AoA is a receiving direction of the signal RX_SG received by the sensing device 10.

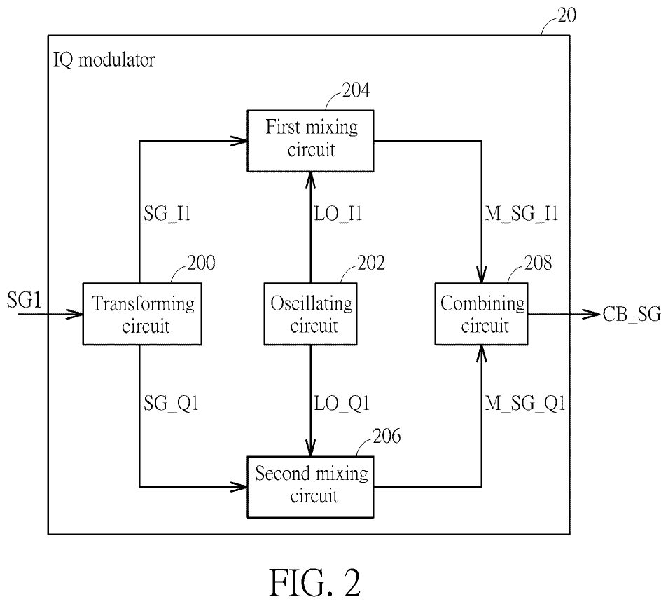

FIG. 2 is a schematic diagram of an IQ modulator 20 according to an example of the present invention. The IQ modulator 20 is comprised in the first adjusting circuit 104 in FIG. 1. The IQ modulator 20 comprises a transforming circuit 200, an oscillating circuit 202, a first mixing circuit 204, a second mixing circuit 206 and a combining circuit 208. The transforming circuit 200 is configured to transform a signal SG1 to an in-phase signal SG_I1 and a quadrature signal SG_Q1. The first mixing circuit 204 is configured to mix the in-phase signal SG_I1 and an output frequency LO_I1 (e.g. cos 2πf_{c}t, wherein f is a carrier frequency) of the oscillating circuit 202, and the second mixing circuit 206 is configured to mix the quadrature signal SG_Q1 and an output frequency LO_I1 (e.g. sin 2πf_{c}t) of the oscillating circuit 202. Then, the combining circuit 208 is configured to combine a mixed in-phase signal M_SG_I1 and a mixed quadrature signal M_SG_Q1 to generate a combined signal CB_SG. In one example, the signal SG1 may be a signal processed in the first adjusting circuit 104. In one example, the combined signal CB_SG may be the first adjusted signal AD_SG1 in FIG. 1. In one example, the transforming circuit 200 comprises a serial to parallel signal converter. In one example, the oscillating circuit 202 comprises a local oscillator. In one example, the first mixing circuit 204 and a second mixing circuit 206 comprise mixers. In one example, the combining circuit 208 comprises an adder.

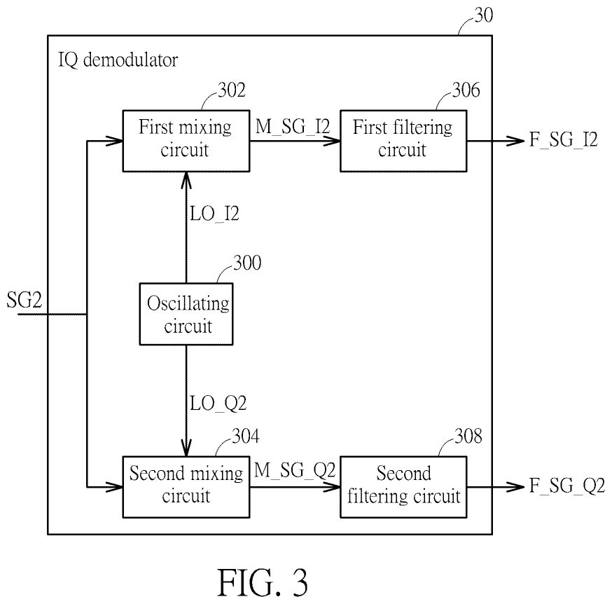

FIG. 3 is a schematic diagram of an IQ demodulator 30 according to an example of the present invention. The IQ demodulator 30 is comprised in the second adjusting circuit 112 in FIG. 1. The IQ demodulator 30 comprises an oscillating circuit 300, a first mixing circuit 302, a second mixing circuit 304, a first filtering circuit 306 and a second filtering circuit 308. The first mixing circuit 302 is configured to mix a signal SG2 and an output frequency LO_I2 (e.g. cos 2πf_{c}t) of the oscillating circuit 300, and the second mixing circuit 304 is configured to mix the signal SG2 and an output frequency LO_I2 (e.g. sin 2πf_{c}t of the oscillating circuit 300. Then, the first filtering circuit 306 is configured to filter a mixed in-phase signal M_SG_I2 to generate a filtered in-phase signal F_SG_I2. The second filtering circuit 308 is configured to filter a mixed quadrature signal M_SG_Q2 to generate a filtered quadrature signal F_SG_Q2. In one example, the signal SG2 may be the received signal RX_SG in FIG. 1. In one example, the mixed in-phase signal M_SG_I2 and the mixed quadrature signal M_SG_Q2 are signals processed in the second adjusting circuit 112. In one example, the oscillating circuit 300 comprises a local oscillator. In one example, the first mixing circuit 302 and a second mixing circuit 304 comprise mixers. In one example, the first filtering circuit 306 and the second filtering circuit 308 comprise low pass filters (LPFs).

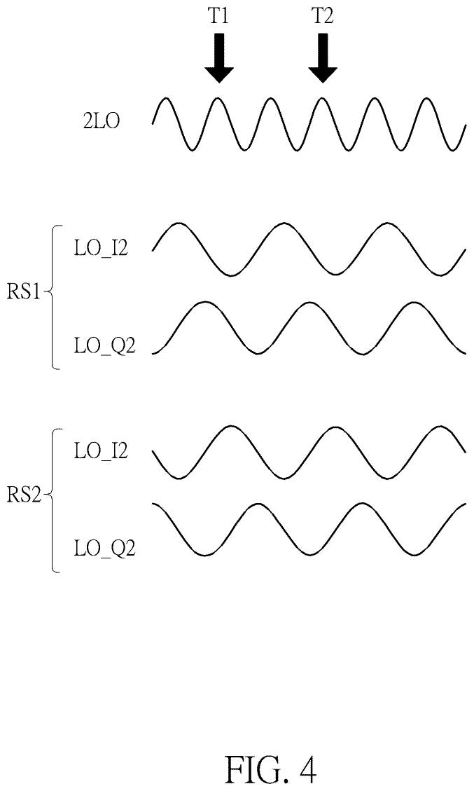

In one example, the oscillating circuit 300 is configured to generate a doubled oscillation frequency and perform a frequency division in order to reduce an impact of the oscillation path. It should be noted that there is an IQ phase difference for the output frequencies LO_I2 and LO_Q2 of the oscillating circuit 300 due to different time instants of capturing the double oscillation frequency. In FIG. 4, time instants of the oscillating circuit 300 capturing the double oscillation frequency are T1 and T2. At the time instant T1, a frequency division result of the oscillating circuit 300 is the output frequencies LO_I2 and LO_Q2 in RS1. At the time instant T2, a frequency division result of the oscillating circuit 300 is the output frequencies LO_I2 and LO_Q2 in RS2. There is an IQ phase difference 180° for the output frequencies LO_I2 and LO_Q2 between the frequency division results RS1 and RS2. This phenomenon causes the second transformed signal TR_SG2 in FIG. 1 to have different values (e.g. the values of the second conversion signal TR_SG2 differ by a negative sign). Similarly, the IQ modulator 20 has the same problem, i.e., the first adjusted signal AD_SG1 in FIG. 1 has different values (e.g. the values of the first adjusted signal AD_SG1 differ by a negative sign). Thus, the compensating circuit 114 compensates the second conversion signal TR_SG2 to solve this problem.

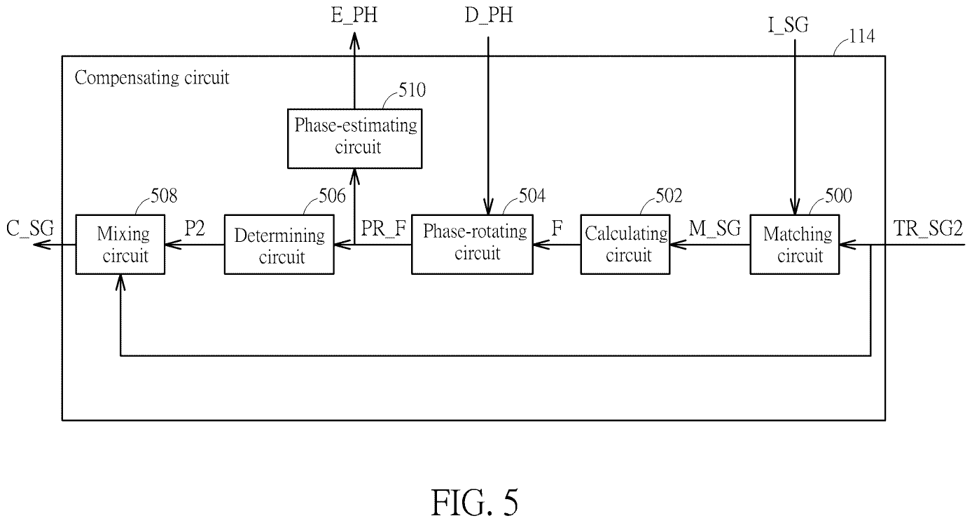

FIG. 5 is a schematic diagram of a compensating circuit 114 according to an example of the present invention. The compensating circuit 114 comprises a matching circuit 500, a calculating circuit 502, a phase-rotating circuit 504, a determining circuit 506, a mixing circuit 508 and a phase-estimating circuit 510. In detail, the matching circuit 500 is coupled to the signal generating circuit 100 and the second transforming circuit 112, and is configured to match the initial signal I_SG and the second transformed signal TR_SG2 to generate the matched signal M_SG. The calculating circuit 502 is coupled to the matching circuit 500, and is configured to calculate a function F of the matched signal M_SG. The phase-rotating circuit 504 is coupled to the calculating circuit 502 and the phase-determining circuit 118 in FIG. 1, and is configured to rotate (or adjust) a phase of the function F according to the determined phase D_PH to generate a phase-rotated function PR_F. The determining circuit 506 is coupled to the phase-rotating circuit 504, and is configured to determine a parameter P2 according to the phase-rotated function PR_F. The mixing circuit 508 is coupled to the determining circuit 506, and is configured to mix the parameter P2 and the second transformed signal TR_SG2 to generate a compensated signal C_SG. In one example, the phase-estimating circuit 510 is coupled to the phase-rotating circuit 504 and the phase-determining circuit 118 in FIG. 1, and is configured to estimate a phase of the phase-rotating circuit 504 according to the phase-rotated function PR_F to generate an estimated phase E_PH.

In one example, the step of the matching circuit 500 matching the initial signal I_SG and the second transformed signal TR_SG2 to generate the matched signal M_SG comprises: generating a coefficient according to the initial signal I_SG; and mixing the coefficient and the second transformed signal TR_SG2 to generate the matched signal M_SG. In one example, the function F is a mean of the matched signal M_SG. In one example, the calculating circuit 502 calculates the mean of the matched signal M_SG via an inverse Fourier transform (IFT). In one example, the step of the determining circuit 506 determining the parameter P2 according to the phase-rotated function PR_F comprises: determining the parameter P2 as a first value in response to the phase-rotated function PR_F being greater than a threshold; and determining the parameter P2 as a second value in response to the phase-rotated function PR_F being smaller than the threshold. In one example, the first value is greater than the second value. In one example, the first value is a positive value (e.g. 1, but not limited herein), and the second value is a negative value (e.g. −1, but not Limited herein). In one example, the threshold is 0, is but not limited herein.

The following example is used for illustrating how the compensating circuit 114 compensates the IQ phase difference. First, a delay of the transmitter-to-receiver (T2R) leakage is less than 350 nanoseconds (ns) according to an experimental result. Accordingly, the input signal y(t) (i.e. the second transformed signal TR_SG2 in FIG. 5) of the compensating circuit 114 is delayed by 350 ns, and matched with the other input signal x (t) (i.e. the initial signal I_SG in FIG. 5) of the compensating circuit 114. The input signal y(t) is shown as follows:

$$y ( t ) = α h ( t ) * x ( t ) + n ( t ) \qquad ( Eq . 1 )$$

wherein α is a compensating parameter (i.e. the parameter P2 in FIG. 5), h(t) is an equivalent filter response (e.g. channel impulse response) except for the reflection path between the transmitter and receiver, and n(t) is a noise. The matching circuit 500 generates the coefficient g(t) according to the input signal x(t) as follows:

$$g ( t ) = {x}^{*} ( T - t ) \qquad ( Eq . 2 )$$

wherein T is 350 ns. Then, the matching circuit 500 mixes the coefficient g(t) and the input signal y(t) to obtain a matched signal y₀(t). The matched signal y₀(t) is shown as follows:

$$\begin{matrix}{y}_{0} ( t ) = α h ( t ) * x ( t ) * g ( t ) + n ( t ) * g ( t ) \\ = α h ( t ) * x ( t ) * x ( T - t ) + n ( t ) * x ( T - t )\end{matrix} \qquad ( Eq . 3 )$$

The matched signal y₀(t) is transformed to a matched signal Y₀(f) (i.e. the matched signal M_SG) via the Fourier transform as follows:

$$\begin{matrix}{Y}_{o} ( f ) = α H ( f ) X ( f ) {X}^{*} ( f ) exp ( - j 2 π fT ) + N ( f ) {X}^{*} ( f ) exp ( - j 2 π fT ) \\ = α H ( f ) {\vert X ( f ) \vert}^{2} exp ( - j 2 π fT ) + N ( f ) {X}^{*} ( f ) exp ( - j 2 π fT )\end{matrix} \qquad ( Eq . 4 )$$

The noise can be ignored, because a signal-to-noise ratio (SNR) of a path from the transmitter to the receiver is very high. Accordingly, the matched signal Y₀(f) can be rewritten as follows:

$${Y}_{o} ( f ) ≅ α H ( f ) {\vert X ( f ) \vert}^{2} exp ( - j 2 π fT ) \qquad ( Eq . 5 )$$

The calculating circuit 502 calculates a mean Mean (i.e. the function F in FIG. 5) of the matched signal y₀(t) via the IFT as follows:

$$\begin{matrix}Mean = \frac{{\int }_{0}^{T} {y}_{o} ( t ) dt}{T} ≅ \frac{α}{T} H ( 0 ) {\vert X ( 0 ) \vert}^{2} exp ( - j 2 π \times 0 \times T ) \\ = \frac{α}{T} H ( 0 ) {\vert X ( 0 ) \vert}^{2} \\ = \frac{α}{T} \vert H ( 0 ) \vert {\vert X ( 0 ) \vert}^{2} exp ( j 2 π∠ H ( 0 ) )\end{matrix} \qquad ( Eq . 6 )$$

wherein H(f) is a fixed value. Then, the phase-rotating circuit 504 maximizes an absolute value of the real part of the mean Mean by adjusting a phase (i.e. the determined phase D_PH) of the phase-rotating circuit 504, which is equivalent to deleting the phase of ∠H(0) (i.e. rotating the phase of the mean Mean). Accordingly, an output Mean_{PR} (i.e. the phase-rotated function PR_F in FIG. 5) of the phase-rotating circuit 504 has the following two values:

$${Mean}_{PR} = \{ \begin{matrix}\frac{\vert H ( 0 ) \vert {\vert X ( 0 ) \vert}^{2}}{T} , & if {Ph}_{Dif} = 0 ° \\ \frac{- \vert H ( 0 ) \vert {\vert X ( 0 ) \vert}^{2}}{T} , & if {Ph}_{Dif} = 180 °\end{matrix} \qquad ( Eq . 7 )$$

wherein Ph_{Dif} is a differential phase. It should be noted that the output Mean_{PR} of the phase-rotating circuit 504 can be prevented from being 0 by rotating the phase of the mean Mean by the phase-rotating circuit 504 (e.g. the phase-rotating circuit 504 rotates the phase of the mean Mean to 45°, but not limited herein). Accordingly, the determining circuit 506 determines the compensating parameter a according to the Equation (Eq. 8) as follows:

$$α = \{ \begin{matrix}1 , & if {Mean}_{PR} > 0 \\ - 1 , & if {Mean}_{PR} < 0\end{matrix} \qquad ( Eq . 8 )$$

Finally, the mixing circuit 508 mixes the compensating parameter a and the input signal y(t) to compensate the input signal y(t).

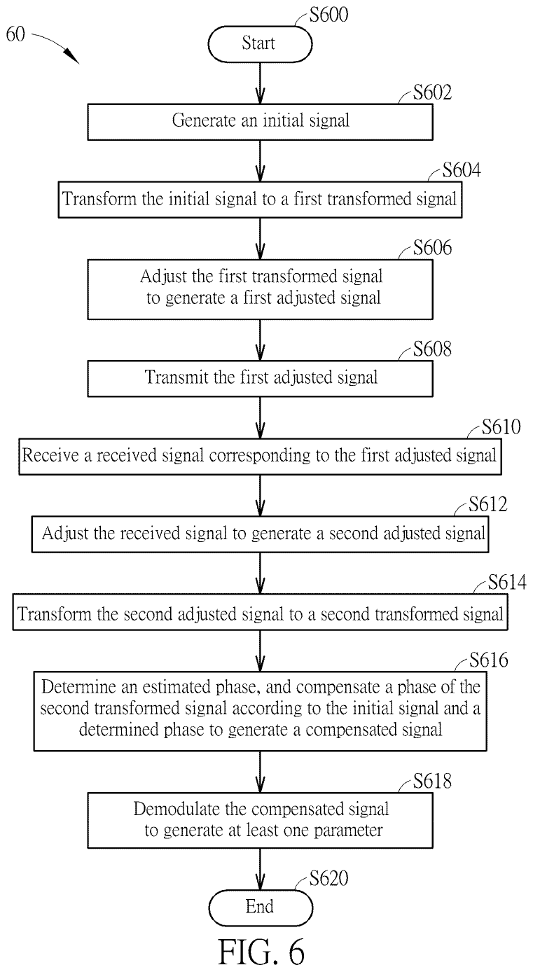

Operations of the sensing device 10 in the above examples can be summarized into a process 60 shown in FIG. 6, which includes the following steps:
Step S600: Start.
Step S602: Generate an initial signal.
Step S604: Transform the initial signal to a first transformed signal.
Step S606: Adjust the first transformed signal to generate a first adjusted signal.
Step S608: Transmit the first adjusted signal.
Step S610: Receive a received signal corresponding to the first adjusted signal.
Step S612: Adjust the received signal to generate a second adjusted signal.
Step S614: Transform the second adjusted signal to a second transformed signal.
Step S616: Determine an estimated phase, and compensate a phase of the second transformed signal according to the initial signal and a determined phase to generate a compensated signal.
Step S618: Demodulate the compensated signal to generate at least one parameter.
Step S620: End.

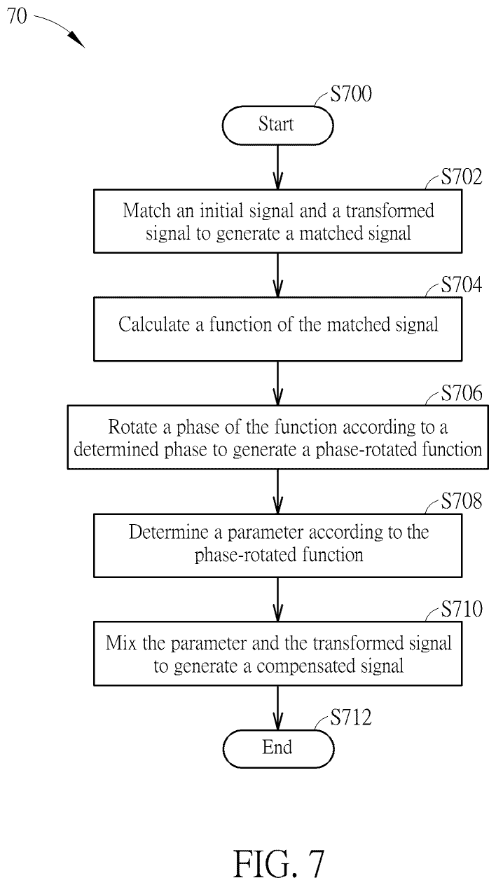

Operations of the compensating circuit 114 in the above examples can be summarized into a process 70 shown in FIG. 7, which includes the following steps:
Step S700: Start.
Step S702: Match an initial signal and a transformed signal to generate a matched signal.
Step S704: Calculate a function of the matched signal.
Step S706: Rotate a phase of the function according to a determined phase to generate a phase-rotated function.
Step S708: Determine a parameter according to the phase-rotated function.
Step S710: Mix the parameter and the transformed signal to generate a compensated signal.
Step S712: End.

The processes 60 and 70 are respectively used for illustrating the operations of the sensing device 10 and the compensating circuit 114. A detailed description and variations of the processes 60 and 70 can be known by referring to the above description, and are not narrated herein.

It should be noted that there are various possible realizations of the sensing device 10, the compensating circuit 114 and the circuits included in the sensing device 10 and the compensating circuit 114. For example, the devices (circuits) mentioned above may be integrated into one or more devices (circuits). In addition, the sensing device 10, the compensating circuit 114 and the circuits in the sensing device 10 and the compensating circuit 114 may be realized by hardware (e.g., circuits), software, firmware (known as a combination of a hardware device, computer instructions and data that reside as read-only software on the hardware device), an electronic system or a combination of the devices mentioned above, but are not limited herein.

The terms of “first” and “second” described above are used to distinguish the relevant statements, and do not limit the order of the relevant statements. The operation of “determine” described above may be replaced by the operation of “compute”, “calculate”, “obtain”, “generate”, “output, “use”, “choose/select”, “decide” or “is configured to”. The phrase “according to” described above may be replaced by “in response to”. The term “corresponding to” described above may be replaced by “of” or “associated with”. The term “comprise” described above may be replaced by “is/are”.

To sum up, the present invention provides a compensating circuit and a compensating method for compensating the IQ phase difference in order to improve the sensing accuracy. The sensing device comprises the compensating circuit. By receiving the initial signal and the transformed signal, the compensating circuit calculates the function and rotates the phase of the function to determine the parameter, and compensates the IQ phase difference using the parameter. Thus, the problem of improving the sensing accuracy of the sensing device can be solved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A compensating circuit, comprising:
a matching circuit, for matching an initial signal and a transformed signal to generate a matched signal;
a calculating circuit, coupled to the matching circuit, for calculating a function of the matched signal;
a phase-rotating circuit, coupled to the calculating circuit, for rotating a phase of the function according to a determined phase to generate a phase-rotated function;
a determining circuit, coupled to the phase-rotating circuit, for determining a parameter according to the phase-rotated function; and
a mixing circuit, coupled to the determining circuit, for mixing the parameter and the transformed signal to generate a compensated signal.

2. The compensating circuit of claim 1, wherein the step of the matching circuit matching the initial signal and the transformed signal to generate the matched signal comprises:
generating a coefficient according to the initial signal; and
mixing the coefficient and the transformed signal to generate the matched signal.

3. The compensating circuit of claim 1, wherein the initial signal comprises a chirp signal.

4. The compensating circuit of claim 1, wherein the function is a mean of the matched signal.

5. The compensating circuit of claim 4, wherein the calculating circuit calculates the mean of the matched signal via an inverse Fourier transform (IFT).

6. The compensating circuit of claim 1, wherein the step of the determining circuit determining the parameter according to the phase-rotated function comprises:
determining the parameter as a first value in response to the phase-rotated function being greater than a threshold; and
determining the parameter as a second value in response to the phase-rotated function being smaller than the threshold.

7. The compensating circuit of claim 6, wherein the first value is a positive value, and the second value is a negative value.

8. The compensating circuit of claim 1, further comprising:
a phase-estimating circuit, coupled to the phase-rotating circuit, for estimating a phase of the phase-rotating circuit according to the phase-rotated function to generate an estimated phase.

9. A compensating method, comprising:
matching an initial signal and a transformed signal to generate a matched signal;
calculating a function of the matched signal;
rotating a phase of the function according to a determined phase to generate a phase-rotated function;
determining a parameter according to the phase-rotated function; and
mixing the parameter and the transformed signal to generate a compensated signal.

10. The compensating method of claim 9, wherein the step of matching the initial signal and the transformed signal to generate the matched signal comprises:
generating a coefficient according to the initial signal; and
mixing the coefficient and the transformed signal to generate the matched signal.

11. The compensating method of claim 9, wherein the initial signal comprises a chirp signal.

12. The compensating method of claim 9, wherein the function is a mean of the matched signal.

13. The compensating method of claim 12, wherein the mean of the matched signal is calculated via an inverse Fourier transform (IFT).

14. The compensating method of claim 9, wherein the step of determining the parameter according to the phase-rotated function comprises:
determining the parameter as a first value in response to the phase-rotated function being greater than a threshold; and
determining the parameter as a second value in response to the phase-rotated function being smaller than the threshold.

15. The compensating method of claim 14, wherein the first value is a positive value, and the second value is a negative value.

16. The compensating method of claim 9, further comprising:
estimating a phase of a phase-rotating circuit according to the phase-rotated function to generate an estimated phase.
